(19) United States
(12) Patent Application Publication
(10) Pub. No.: US 2008/0191252 A1
(43) Pub. Date: Aug. 14, 2008

(54) SEMICONDUCTOR DEVICE AND METHOD FOR MANUFACTURING THE SEMICONDUCTOR DEVICE

(75) Inventors: Ko NAKAMURA, Kawasaki (JP); Aki DOTE, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/957,636

(22) Filed: Dec. 17, 2007

(30) Foreign Application Priority Data
Feb. 14, 2007 (JP) 2007-32872

(51) Int. Cl. H01L 29/92; H01L 21/28

(52) U.S. Cl. 257/295; 438/3; 257/E21.008; 257/E29.342

(57) ABSTRACT

A semiconductor device with a first insulating film formed on a semiconductor substrate; a capacitor formed on the first insulating film and including a lower electrode, a ferroelectric film and an upper electrode; a second insulating film formed on the capacitor and the first insulating film; a first contact hole formed in the second insulating film; and a first conductive plug formed in the first contact hole and having a multilayer structure and including a first aluminum film.

### CROSS-REFERENCE TO RELATED APPLICATIONS

This application is based upon and claims the benefit of priority from the prior Japanese Patent Application No. 2007-032872, filed on Feb. 14, 2007, the entire contents of which are incorporated herein by reference.

### TECHNICAL FIELD

The present invention relates to a semiconductor device and a method for manufacturing the semiconductor device.

### BACKGROUND

A volatile memory element such as Dynamic Random Access Memory (DRAM), Static Random Access Memory (SRAM), and a nonvolatile memory element such as FLASH memory are used in various fields.

On the other hand, Ferro-electric Random Access Memory (FeRAM), Magnetoresistive Random Access Memory (MRAM), and Phase change Random Access Memory (PRAM) are promising as memory devices which have the characteristics of high-speed and low-voltage operation of DRAM and nonvolatility of FLASH memory. The research and development is advancing and a part of them have been mass-produced.

FeRAM is an element including a ferroelectric capacitor having a structure in which a ferroelectric layer is sandwiched between an upper electrode and a lower electrode on a substrate, wherein writing and reading information by using hysteresis characteristics in accordance with the relation between the polarization charge amount and the voltage of the ferroelectric material.

A ferroelectric film includes a metal oxide insulating material such as lead zirconate titanate (PZT) and strontium bismuth tantalate (SBT). However, the ferroelectric film has a problem that the electrical property deteriorates when the ferroelectric film is put under the environment where temperature is high and hydrogen and water exist. This is because the ferroelectric film is reduced by hydrogen and water and thereby loses its ferroelectric property.

Hydrogen and water may intrude from outside, therefore it is necessary to be most cautious about their intrusion during the ferroelectric memory manufacturing process. Depending on the process, for example if an interlayer insulating film is formed by a chemical vapor deposition (CVD) method, large amounts of hydrogen may be used and hydrogen may be generated by degradation of materials. In addition, hydrogen residue and moisture remaining in the interlayer insulating film might have a negative influence on the ferroelectric film.

To solve these problems, a protective film to prevent hydrogen and moisture from intruding into the ferroelectric capacitor might be used.

U.S. Pat. Nos. 6,611,014 and 6,982,453 describe a structure in which the surface of the ferroelectric capacitor is covered with a hydrogen barrier film formed by any one of Al₂O₃, AlₓO_{y}, AlNi, WN, SrRuO₃, IrOₓ, ZrOₓ, RuOₓ, SrOₓ, ReOₓ, OsOₓ and MgOₓ to prevent hydrogen from intruding into the ferroelectric capacitor.

U.S. Pat. Nos. 6,740,531 and 7,023,037 describe a structure in which the surface of the ferroelectric capacitor is covered with a blocking film formed by any one of Al₂O₃, TiO₂, ZrO₂, Ta₅O₃, and CeO₂ to prevent hydrogen from intruding into the ferroelectric capacitor. These also describe that protection effect against hydrogen intrusion from the upper part of a contact hole is improved by covering the contact metal with a protective film made from the similar materials after forming the contact metal connected to the ferroelectric capacitor as well.

U.S. Pat. No. 7,132,709 describes a method to use a film including less moisture for the interlayer insulation film closer to the ferroelectric capacitor among two interlayer insulation films covering the ferroelectric capacitor, and to form a barrier film to cover the ferroelectric capacitor on the same layer as the first wiring layer on the upper side of the ferroelectric capacitor to prevent hydrogen from intruding into the ferroelectric capacitor. As the barrier layer, at least one film can be selected from a titanium film, a titanium oxide film, a tantalum film, a tantalum oxide film, an alumina film, a silicon nitride film, a silicon oxide nitride film, an aluminum titanium nitride film, and a titanium-aluminum alloy film.

Though these methods are effective against the intrusion of hydrogen and moisture from the upper and lateral sides of the ferroelectric capacitor, they are not effective against the intrusion of hydrogen and moisture from the contact hole formed on the ferroelectric capacitor.

Currently, as the size of the ferroelectric memory decreases, the contact hole diameter also decreases, and in place of sputter method a CVD method is used to fill a conductive material in the contact hole. Among various contact holes, tungsten (W) or polysilicon may be filled in the contact hole part on the electrode upper side of the ferroelectric capacitor. However, a CVD method uses large amounts of hydrogen to form a film and generates hydrogen during the degradation process of materials.

However, in the conventional structure, the ferroelectric capacitor may deteriorate due to hydrogen generated when a conductive material is filled in the contact hole.

U.S. Pat. Nos. 6,188,098 and 6,395,612 disclose the structure in which films of conductive nitride such as TiN and TaN of about 100 angstrom or more thickness are formed under the contact holes to secure the tolerance of hydrogen intrusion from the contact hole parts.

Japanese Patent Application Laid-open No. 2005-57103 discloses a method to form a first hydrogen barrier layer that covers the ferroelectric capacitor and prevents hydrogen from diffusing, to form a spacer insulating film on it, then to polish the interlayer insulation film and the first hydrogen barrier layer by a Chemical Mechanical Polish (CMP) method until the upper electrode of the ferroelectric capacitor is exposed, and consequently to form a second hydrogen barrier layer that is conductive and touches the exposed upper electrode and the first hydrogen barrier layer on the interlayer insulating film.

In this method, at least one material selected from a group of SiN, SiON, Al₂O₃, TiAlO, TaAlO, TiSiO and TaSiO is used as the first hydrogen barrier layer, and at least one material selected from a group of TiAlN, TiAl, TaAlN, TaAl, TiSiN, TaSiN, Ti and Ta is used as the second hydrogen barrier layer.

This method can prevent the ferroelectric from deteriorating even in a hydrogen atmosphere during contact metal formation because the contact hole parts are covered with films having tolerance against hydrogen intrusion.

However, even adopting a structure in which films of conductive nitride such as TiN and TaN of 100 angstrom or more thickness are formed under contact holes, as described in U.S. Pat. No. 6,188,098 and U.S. Pat. No. 6,395,612 is not an effective solution because the tolerance of hydrogen intrusion of TiN or TaN itself is not too strong.

On the other hand, when the structure and the method described in Japanese Patent Application Laid-open No. 2005-57103 are adopted, heat treatment to recover ferroelectric crystal cannot be performed at all after the second hydrogen barrier layer is formed because the second hydrogen barrier layer comprises a material that is impermeable to oxygen. Also, the structure and the method add an additional five steps that are the formation of the interlayer insulating film to cover the ferroelectric capacitor, CMP that exposes the upper electrode of the ferroelectric, the formation of the second hydrogen barrier film, the patterning of the mask of the second hydrogen barrier film and the etching of the second hydrogen barrier film from the formation of the first hydrogen barrier film to the formation of the contact holes.

### SUMMARY

The present invention is directed to various embodiments of a semiconductor device and a method for manufacturing the semiconductor device having a multilayer structure with aluminum film as a conductive plug material filled in a contact hole formed on the upper electrode of the capacitor.

### BRIEF DESCRIPTION OF THE DRAWINGS

FIG. 1A to FIG. 1J are a sectional view that shows the manufacturing steps regarding the semiconductor device of an embodiment of the present invention.

FIG. 2A to FIG. 1F are a sectional view that shows the forming steps regarding the plug of the semiconductor device of an embodiment of the present invention.

FIG. 3 is an outline configuration of the multi chamber device used to manufacture the semiconductor device of an embodiment of the present invention.

FIG. 4A and FIG. 4B are a sectional view that shows the manufacturing steps regarding the semiconductor device of another embodiment of the present invention.

FIG. 5A to FIG. 5F are a sectional view that shows the forming steps regarding the plug of the semiconductor device of a second embodiment of the present invention.

FIG. 6A and FIG. 6B are a sectional view that shows the ferroelectric capacitor regarding the semiconductor device of a third embodiment of the present invention.

FIG. 7A and FIG. 7B are a sectional view that shows the semiconductor device of a fourth embodiment of the present invention.

### DETAILED DESCRIPTION OF THE EMBODIMENTS

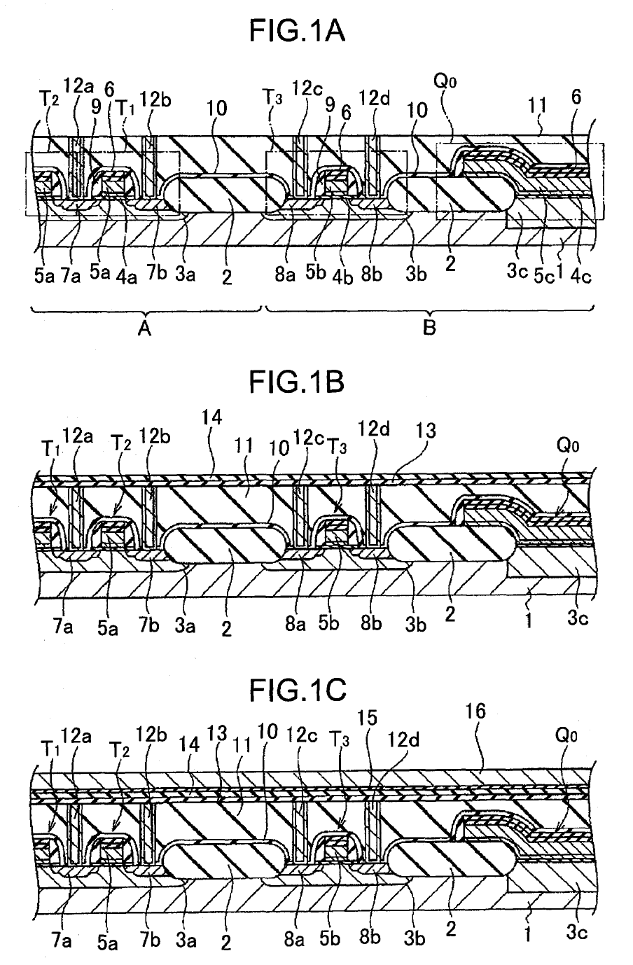

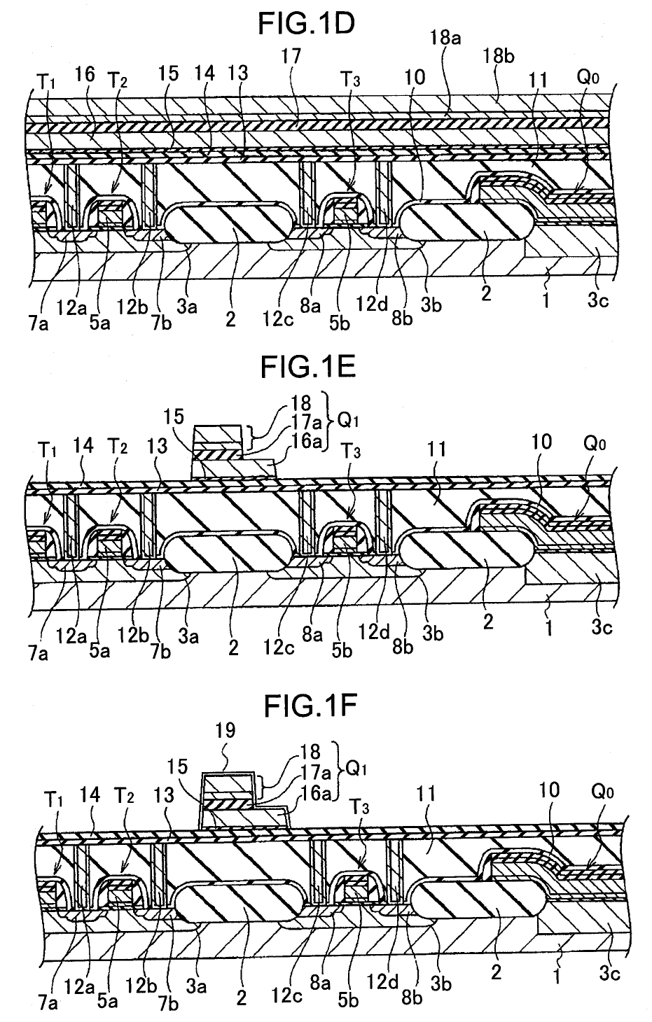

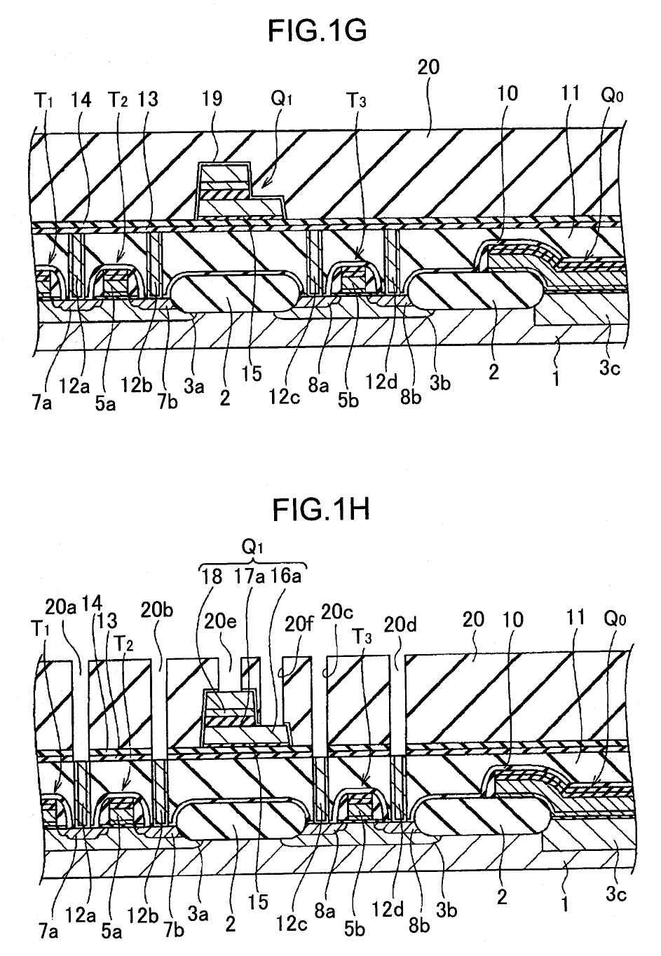

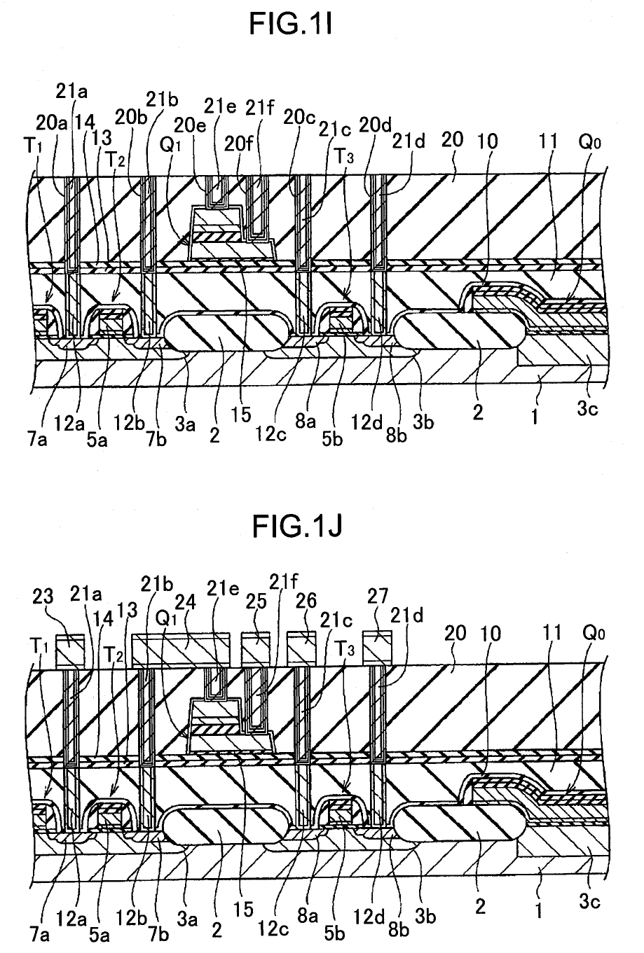

FIG. 1A to FIG. 1J are a sectional view that shows the formation steps regarding the semiconductor device of a first embodiment of the present invention.

First of all, the steps until the cross-section structure shown in FIG. 1A is formed are explained.

In FIG. 1A, an element isolation insulating film 2 is formed on the surface of a p-type or n-type silicon (semiconductor) substrate 1 by a LOCOS (Local Oxidation of Silicon) method. In addition, a Shallow Trench Isolation (STI) structure can also be adopted as the element isolation insulating film 2.

Subsequently, p-type impurities and n-type impurities are selected and introduced to the given active region (transistor formation area) in the memory cell area A and the peripheral circuit area B on the silicon substrate 1. As a result, a first well 3a is formed in the active region of the memory cell area A, and a second well 3b and a third well 3c are formed in the active region of the peripheral circuit area B. In addition, the third well 3c functions as the lower electrode of capacitor Q₀.

After that, the surface of the silicon substrate 1 is thermally-oxidized to form silicon dioxide films that are used as gate insulating films 4a and 4b on each surface of the first well 3a and the second well 3b as well as a capacitor dielectric film 4c of the capacitor Q₀ on the third well 3c.

Next, a polycrystalline or amorphous silicon film and a tungsten silicide film are formed as conductive films in this order on the element isolation insulating film 2, the gate insulating films 4a and 4b, and the capacitor dielectric film 4c. In addition, an insulating film 6 that includes a silicon dioxide film or a silicon nitride film, or a two-layer structure of those two films is formed on the conductive films. Then, the area from the insulating film 6 to the silicon film is patterned to a given shape by a photolithographic method. As a result, two gate electrodes 5a are formed at intervals on the first well 3a, a gate electrode 5b is formed on the upper side of the second well 3b, and an upper wiring 5c of the capacitor Q₀ is formed on the upper side of the third well 3c. The upper surfaces of the gate electrodes 5a and 5b and the upper wiring 5c are covered with the insulating film 6.

In the figures, one of the two gate electrodes 5a on the first well 3a is partially omitted.

The two gate electrodes 5a formed on the upper side of the first well 3a are formed at almost parallel intervals in the memory cell area A and these gate electrodes 5a extend onto the element insulating film 2 and become word lines.

As thus, the silicon substrates 1 on both sides of the two gate electrodes 5a formed on the first well 3a in the memory cell area A via the insulating film 4a, is ion-implanted with impurities that are a reverse conductive type to the first well 3a, and first and second impurity diffusion areas 7a and 7b, and a third n-type impurity diffusion area (not shown) that become the source/drain of the first and second MOS transistor T₁ and T₂ are formed. The first impurity diffusion area 7a located in the center of the first well 3a is electrically connected to the bit line on the upper side, and the second impurity diffusion area 7b and the third impurity diffusion area (not shown) located near sides of the first well 3a are electrically connected to a ferroelectric capacitor described below.

Subsequently, among the second well 3b in the peripheral circuit area B, the silicon substrates 1 on both sides of the gate electrode 5b, is ion-implanted with impurities that are a reverse conductive type to the second well 3b and a fourth and a fifth impurity diffusion areas 8a and 8b that become the source/drain of a third MOS transistor T₃ are formed.

After that, insulating films are formed on the silicon substrate 1, the element isolation insulating film 2 and gate electrodes 5a and 5b. Then, by etching back the insulating films, the insulating films are left as sidewall insulating films 9 on the sides of the gate electrode 5a and 5b. As the insulating film, for example, silicon dioxide (SiO₂) formed by a CVD method is used.

Further, the two gate electrodes 5a on the upper side of the first well 3a and the sidewall insulating film 9 are masked, impurities are ion-implanted to the first and the second impurity diffusion areas 7a and 7b and the third impurity diffusion area (not shown) to make those impurity diffusion areas 7a and 7b a LDD structure. In addition, the gate electrode 5c on the second well 3b and the sidewall insulating film 6 are masked, impurities are ion-implanted to the fourth and the fifth impurity diffusion areas 8a and 8b to make those impurity diffusion areas 8a and 8b a LDD structure.

As a result, the first MOS transistor T₁ including the first and the second impurity diffusion areas 7a and 7b and the gate electrodes 5a, and the second MOS transistor T₂ including the second n-type impurity diffusion area 7b and the third n-type impurity diffusion area (not shown) and the gate electrodes 5a are formed. In addition, the third MOS transistor T₃ including the fourth and the fifth impurity diffusion areas 8a and 8b and the gate electrode 5b is formed.

After that, a cover film 10 to cover the first, the second and the third MOS transistors T₁, T₂, T₃, and the capacitor Q0 on the silicon substrate 1 are formed by a plasma CVD method. As a cover film 10, for example a silicon oxynitride (SiON) film is formed.

Next, a silicon dioxide (SiO₂) film is grown by a plasma CVD method using tetraethoxysilane (TEOS) gas. This oxide silicon film is used as a first interlayer insulating film 11.

Subsequently, a densification treatment to the first interlayer insulating film 11 is performed by heat treating the first interlayer insulating film 11 in the presence of oxygen at 650° C. for 10 minutes at normal pressures. After that, polishing and planarizing of the upper surface of the first interlayer insulation film 11 is performed by a CMP (chemical mechanical polishing) method.

Next, the first interlayer insulating film 11 and the cover film 10 under it are patterned by a photolithographic method using photoresist and etching, and contact holes are formed on the first to the fifth impurity diffusion areas 7a, 7b, 8a, 8b (the third impurity diffusion area is not shown in FIG. 1A to FIG. 1J). Further, a titanium (Ti) film and a titanium nitride (TiN) film as adhering (adhesion) films are formed in this order on the inner surface of each contact hole and the upper surface of the first interlayer insulating film 11. In addition, a tungsten (W) film is grown on the TiN film by a CVD method using tungsten hexafluoride (WF₆) as a source gas, completely filling in the contact holes on the first to the fifth impurity diffusion areas 7a, 7b, 8a, 8b.

Subsequently, the W film, the TiN film and the Ti film are removed from the upper surface of the first interlayer insulating film 11 by a CMP method. Then, the W film, the TiN film and the Ti film remaining in each contact hole of the first to the fifth impurity diffusion areas 7a, 7b, 8a and 8b are used as first conductive plugs 12a to 12d in the first layer.

After that, as shown in FIG. 1B, an antioxidant insulating film 13 including silicon oxynitride (SiON) and an underlayer insulating film 14 including SiO₂ are formed in order by a plasma CVD method with the thickness of about 100 nm each on the first interlayer insulating film 11 and on the conductive plugs 12a to 12d of the first layer. To grow the SiO₂ film, TEOS is used as a source gas. The antioxidant insulating film 13 is formed in order to prevent the conductive plugs 12a to 12d in the first layer from being anomalously oxidized and causing contact failure at heat treatment by subsequent anneal described below.

Next, as shown in FIG. 1C, an alumina (Al₂O₃) film is formed on the underlayer insulating film 14 as a glue film 15 by sputter. After that, the alumina film is oxidized in the presence of oxygen at 650° C. by rapid heat treatment. The glue film 15 is formed to improve the adhesion of the lower electrode and the underlayer insulating film 14 described below.

Subsequently, a platinum (Pt) film as lower electrode layer 16 with the thickness of about 50 to 300 nm, for example about 150 nm is formed on the glue film 15.

After that, as shown in FIG. 1D, a ferroelectric film 17 including PLZT ((Pb, La)(Zr, Ti)O₃) that becomes a capacitor dielectric film of the ferroelectric capacitor is formed on the lower electrode layer 16 by a sputtering method in an amorphous state. Subsequently, rapid heat treatment, for example heat treatment at 575° C. in the presence of 1.25% O₂ for 90 seconds, is performed to the ferroelectric film 17.

Subsequently, a first iridium oxide (IrO₂) film 18a with the thickness of about 25 to 300 nm is formed on the ferroelectric film 17 by a sputter method as a lower layer of the upper electrode of the ferroelectric capacitor. In addition, by performing rapid heating treatment, for example, at 700° C. in the presence of about 1% O₂ for about 20 seconds, the ferroelectric film 17 damaged by the formation of the first IrO₂ film 18a is recovered to its original state. After that, a second IrO₂ film 18b is formed as an upper layer of the upper electrode on the IrO₂ film 18a.

As for methods to form the ferroelectric layer 17, other than the above, there are such as a spin-on method using MOD (metal organic deposition) solution, a MOCVD (organic metal CVD) method, and a spin-on method using sol-gel solution. As for materials of the ferroelectric layer 17, other than the above, there are such as other PZT series materials including PZT and at least one element out of lanthanum (La), strontium (Sr), and calcium (Ca), bismuth layer-structured compound such as SrBi₂Ta₂O₉ and SrBi₂(Ta, Nb)₂O₉, and other metal-oxide ferroelectrics.

Next, a resist pattern (not shown) having a pattern shape of the upper electrode of a ferroelectric capacitor Q₁ is formed on the second IrO₂ film 18b. With this resist pattern as a mask, the first and the second IrO₂ films 18a and 18b are etched. As a result, a capacitor upper electrode 18 including the first and the second IrO₂ films 18a and 18b are formed.

Subsequently, the resist pattern is removed, another resist pattern (not shown) having the pattern shape of the capacitor insulating film of the ferroelectric capacitor is newly formed, and the ferroelectric film 17 is etched using this resist pattern as a mask. As a result, a capacitor insulating film 17a of the ferroelectric capacitor Q1 is obtained from the ferroelectric film 17. The patterned ferroelectric film 17 has a wider shape than the capacitor upper electrode 18, for example, a wider shape in the extended direction of the word line.

After that, the resist pattern is removed; another resist pattern (not shown) having the pattern shape of the lower electrode of the ferroelectric capacitor Q1 is newly formed, and the lower electrode layer 16 and the glue film 15 are etched using this resist pattern as a mask. The patterned lower electrode layer 16 becomes a capacitor lower electrode 16a, sticks out from under the capacitor insulating film 17a, extends in the extended direction of the word line in a stripe structure, and further includes a contact area not covered with the capacitor insulating film 17a and the capacitor upper electrode 18.

The above-mentioned patterning as shown in FIG. 1E forms one ferroelectric capacitor Q₁ including one capacitor upper electrode 18, and the capacitor insulating film 17a and the lower electrode 16a under the capacitor upper electrode 18.

Next, as shown in FIG. 1F, an alumina film with the thickness of about 20 to 50 nm is formed by sputter as a capacitor protection insulating film 19 on the ferroelectric capacitor Q₁, the glue film 15 and the underlayer insulating film 14. As for the capacitor protection insulating film 19, PZT, a silicon nitride film, or a silicon oxynitride film may also be used in place of an alumina film.

Subsequently, by etching the capacitor protection insulating film 19 with a resist mask (not shown), plural areas not covering the ferroelectric capacitor Q₁ are removed. As a result, the underlayer insulating film 14 is exposed.

Next, as shown in FIG. 1G, an oxide silicon film with the thickness of about 1 μm is formed as a second interlayer insulating film 20 on the capacitor protection insulating film 19 and the underlayer insulating film 14. This oxide silicon film is formed using TEOS by a CVD method. Subsequently, the upper surface of the second interlayer insulating film 20 is planarized by a CMP method. In this example, the film thickness of the second interlayer insulating film after CMP is determined to be about 300 nm on the ferroelectric capacitor Q₁ in the memory cell area A.

Subsequently, a resist pattern (not shown) to form a via is formed on the second interlayer insulating film 20. By patterning the second interlayer insulating film 20, the underlayer insulating film 14 and the antioxidant insulating film 13, as shown in FIG. 1H, the first to the fourth via holes 20a to 20d are formed respectively on the conductive plugs 12a to 12d in the first layer in the first to the fourth impurity diffusion areas 7a, 7b, 8a and 8b. At the same time, first and second contact holes 20e and 20f are formed in the contact area on the upper surface of the capacitor upper electrode 18 and the upper surface of the lower electrode 16 in the ferroelectric capacitor Q₁.

After that, as shown in FIG. 1I, first to fourth conductive plugs 21a to 21d of the second layer are formed in the first to the fourth via holes 12a to 12d as well as a fifth and a sixth conductive plugs 21e and 21f of the second layer are formed in the first and the second contact holes 20e and 20f.

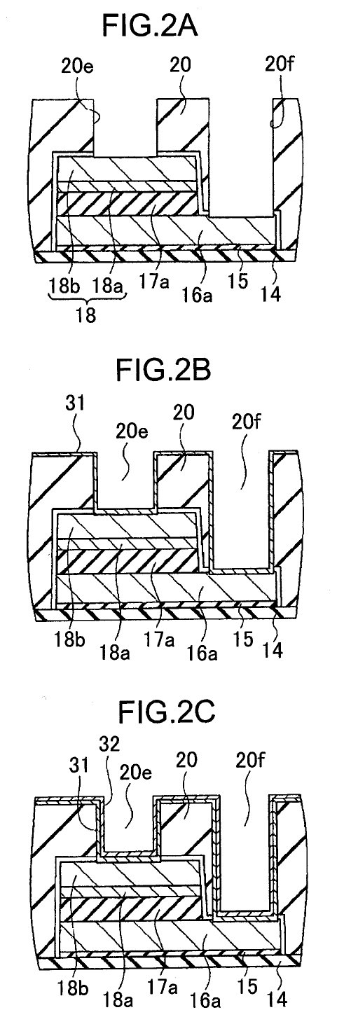

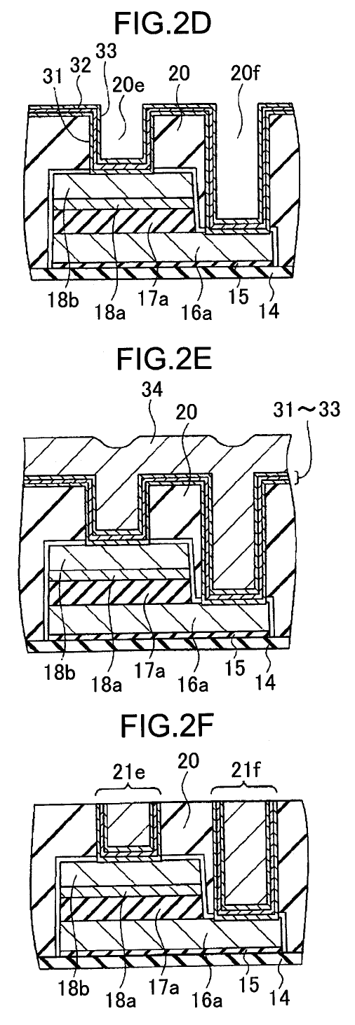

Among the first to the sixth conductive plugs 21a to 21f, at least the conductive plugs 21e and 21f on the ferroelectric capacitor Q1 are formed by a method, for example as shown in FIG. 2A to FIG. 2F.

First of all, as shown in FIG. 2A, RF sputter processing is performed for the purpose of removing natural oxide films, resist residues and etching residues inside the contact holes such as 20e and 20f opened on the capacitor upper electrode 18 and the lower electrode 16a among the second interlayer insulating film 20. RF sputter processing is performed by introducing Ar gas into a reduced-pressure atmosphere.

Continuously, as shown in FIG. 2B, a TiN film 31 of a first layer is formed as a glue film along the internal surfaces of the fifth and the sixth contact holes 20e and 20f and the upper surface of the second interlayer insulating film 20. To fill the TiN film 31 in the contact holes 20e and 20f with good coverage, it is preferable to use a SIP (Self-Ionized Plasma) sputtering and SIP-EnCore (Enhanced Coverage by Re-sputtering) sputtering. As conditions of such a sputter, for example, argon gas (Ar) and nitrogen gas (N2) are introduced into a sputter atmosphere and the substrate temperature is set, for example, to about 200° C.

The SIP sputtering realizes a high ionization density in high-density plasma by applying a high DC voltage on the magnetic field distribution with strong electronic confinement capability. In this case, characteristics of excellent coverage and low overhang at a contact hole are obtained by applying high-frequency bias to the substrate side.

SIP-EnCoRe sputtering continuously resputters by argon ions in the same chamber after the film is formed once and can control the thickness of the film on the bottom of the contact hole.

Though thicker film thickness is better, too thick causes high resistivity, deteriorates the filling shape of a W film formed in the following step and generates a crack in itself. Considering the above, about 50 nm film thickness is preferable.

Subsequently, as shown in FIG. 2C, an aluminum (Al) film 32 is formed on the TiN film 31 of the first layer. To form the aluminum film 32 as well, SIP sputtering and SIP-EnCoRe sputtering are used. Such sputtering conditions are, for example, using an Al target, introducing Ar gas into the sputtering atmosphere and setting the substrate temperature to about 200° C.

As for the Al film 32 as well, thicker film thickness is better. However too thick deteriorates the filling shape of the W film in the contact holes 20e and 20f. As a result, about 50 nm film thickness is preferable.

Next, as shown in FIG. 2D, the TiN film 33 of the second layer is formed as a glue film on the Al film 32. On forming this film, because the Al film 32 functioning as a H₂ barrier film has already been formed in the contact holes 20e and 30f and on the interlayer insulating film 20, there are broad options in film formation methods to use including not only sputtering methods such as SIP and SIP-EnCoRe but also a CVD method.

However, because all the internal surfaces and the bottom surfaces of the contact holes 20e and 20f, are covered with the Al film 32, it is necessary to select a film formation method of the TiN film 33 having a good coverage. Though thicker film thickness is better, too thick causes high resistivity, deteriorates the filling shape of a W film formed in the following step and generates a crack in itself. Considering the above, about 50 nm film thickness is preferable.

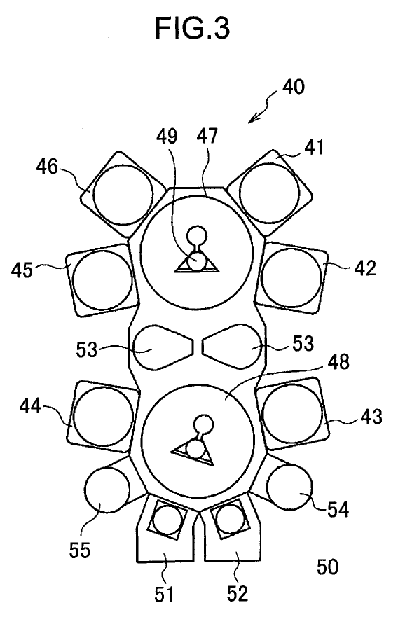

As for these films 31 to 33, it is preferable to form the TiN film 31, the Al film 32 and the TiN film 33 in this order by using a multi chamber device 40 such as ENDURA (registered trademark) having plural process chambers 41 to 46 as shown in FIG. 3, and by changing the process chambers 41 to 46 without exposing the silicon substrate 1 and the film on it to the room's atmosphere.

However, formation of films 31 to 33, is not limited to use of the multi chamber device 40, but it is possible to use a difference device per step. The selection can be changed depending on the situation of device handling.

In FIG. 3, robots 49 and 50 are located in a transfer chamber 47 and a buffer chamber 48 surrounded by plural process chambers 41 to 46, load locks 51 and 52 are located near the buffer chamber 48, and an auxiliary clean chamber 53 is located between the buffer chamber 48 and the transfer chamber 47. In addition, chambers 54 and 55 for orienter and degas are located between the loadlocks 51 and 52 and the process chambers 41 and 42 nearest to the load locks 51 and 52.

Next, a W film 34 is formed by a CVD method using WF₆ as shown in FIG. 2E, and the fifth and sixth contact holes 20e and 20f are completely filled thereby.

After that, the W film 34, the TiN film 33, the Al film 32, and the TiN film 31 are removed from the upper surface of the second interlayer insulating film 20 by a CMP method. As a result, the W film 34, the TiN film 33, the Al film 32, and the TiN film 31 left in the contact holes 20e and 20f as shown in FIG. 2F become the fifth and the sixth conductive plug 21e and 21f of the second layer.

When these fifth and sixth conductive plugs 21e and 21f are formed, as shown in FIG. 1I, at the same time, the W film 34, the TiN film 33, the Al film 32 and the TiN film 31 are left in the first to the fourth contact holes 20a to 20d on the upper side of the impurity diffusion areas 7a, 7b, 8a and 8b. They are used as the first to the fourth conductive plugs 21a to 21d of the second layer.

After that, a metal film is formed on the second interlayer insulating film 20 and the first to the sixth conductive plugs 21a to 21f. As metal films, a TiN film with the film thickness of 150 nm, an aluminum film with the film thickness of 500 nm, a Ti film with the film thickness of 5 nm, and a TiN film with the film thickness of 100 nm are formed in this order on the second interlayer insulating film 20.

Subsequently, by patterning these metal films by a photolithographic method, as shown in FIG. 1J, a conductive pad 23 connected to the first conductive plug 21a of the second layer on the upper side of the conductive plug 12a in the center of the first well 3a, and wirings 23 to 27 connected to the second to the sixth conductive plugs 21b to 21f are formed.

After the conductive pad 23 and wirings 24 to 27 are formed, a third interlayer insulating films is formed and additionally such as a bit line is formed on the third interlayer insulating film, though the details are omitted. As mentioned above, on the second interlayer insulating film 20 with which the ferroelectric capacitor Q1 is covered, when a conductive material such as tungsten is filled by a CVD method in the fifth contact hole 20e formed on the capacitor upper electrode 18, a trilayer structure of the TiN film 31, the Al film 32, and the TiN film 33 is formed on the inner surface of the fifth contact hole 20e as an underlayer film.

In this case, hydrogen generated when growing tungsten by a CVD method is prevented from intruding into the upper electrode 18 by the Al film 32 in the contact holes 20e and 20f, thereby degradation of the ferroelectric film 17 under the capacitor upper electrode 18 by hydrogen reduction is prevented.

In addition, because the Al film 32 is formed not only in the first contact hole 20e but on the second contact hole 20f, on the inner surface of the first to the fourth via hole 20a to 20d, and on the interlayer insulating film 20, hydrogen generated when growing the tungsten film 34 is prevented from intruding into the second interlayer insulating film 20. As a result, hydrogen is prevented from intruding from within the second interlayer insulating film 20 to the ferroelectric capacitor Q1 by heat treatment after the first to the sixth conductive plugs 21a to 21f are formed.

In addition, this structure that the Al film 32 is formed in the contact holes 20a to 20f is an effective structure especially for the contact hole 20e on the capacitor upper electrode 18. However, there is intrusion of hydrogen from the lower electrode 16a to the capacitor insulating film 17a, though the amount is not significant because hydrogen does not also intrude from the capacitor upper electrode 18.

Further, the conductive plug 21f including the Al film 32 can be formed on the lower electrode part as well because applying the same structure to the conductive plug 21e on the capacitor upper electrode 18 and the conductive plug 21f on the lower electrode layer 16 can simplify steps.

In addition, the contact holes 20a to 20d and the conductive plugs 21a to 21d on the conductive plugs 12a to 12d of the first layer can be formed by different steps from those of the contact hole 20e and the contact plug 21e on the capacitor upper electrode 18 due to differences in aspect ratios.

In this case, an Al film needs not be formed in the contact holes 20a to 20d formed on the conductive plugs 12a to 12d of the first layer but it can adopt either growing a tungsten film after one layer of a TiN film is formed or growing a tungsten film after a Ti film and a TiN film are formed.

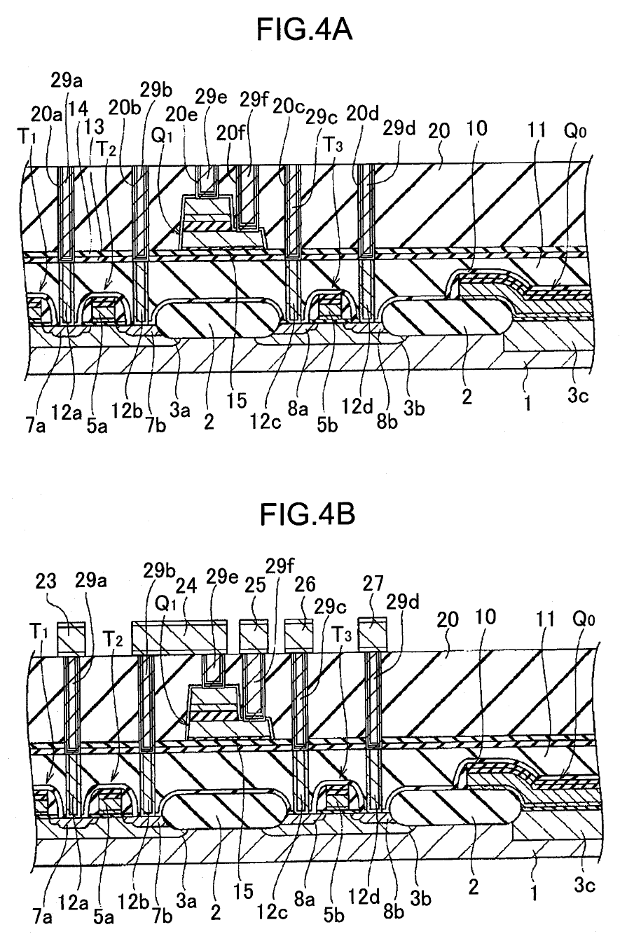

FIG. 4A and FIG. 4B are a sectional view that shows the manufacturing steps regarding the semiconductor device of a second embodiment of the present invention.

FIG. 4A illustrates the manufacturing steps of the semiconductor device of this embodiment, similar to the embodiment shown above, specifically, MOS transistors such as T₁, T₂, and T₃ are formed on the silicon substrate 1, T₁; T₂ and T₃ are covered with the first interlayer insulating film 11; the ferroelectric capacitor Q1 is also formed thereon; ferroelectric capacitor Q1 is covered with the capacitor protective film 19; and, further, the second interlayer insulating film 20 is formed on the capacitor protective film 19 and the first interlayer insulating film 11.

On the second interlayer insulating film 20, the first to the sixth contact holes 20a to 20f are formed by methods similar to the embodiment as shown in FIG. 1H. Then, the first to the sixth conductive plugs 29a to 29f of the second layer are formed in the first to the sixth contact holes 20a to 20f.

The conductive plugs 29e and 29f connected with the ferroelectric capacitor Q1 are formed, for example, with the following steps.

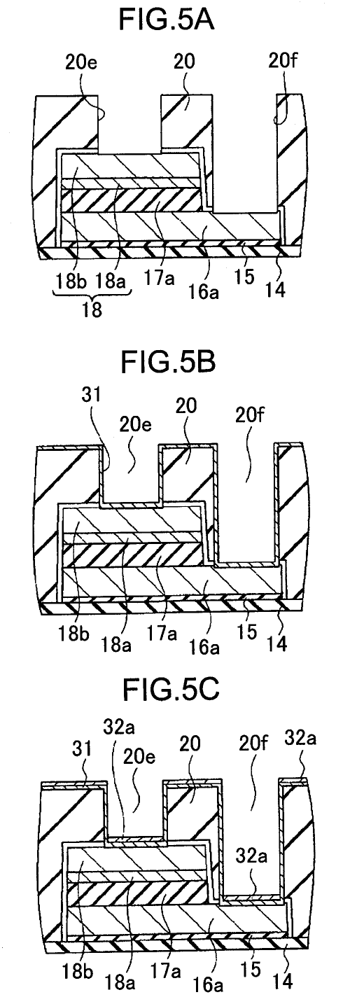

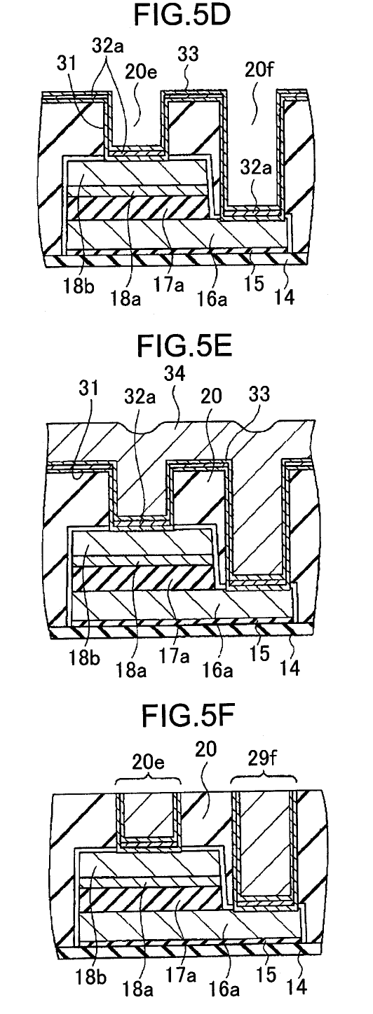

First of all, as shown in FIG. 5A, RF sputter processing is performed for the purpose of removing the natural oxide films, the resist residues and the etching residues inside the fifth and the sixth contact holes 20e and 20f opened on the capacitor upper electrode 18 and the lower electrode 16a among the second interlayer insulating film 20. RF sputter processing is performed by introducing Ar gas into a reduced-pressure atmosphere.

Subsequently, as shown in FIG. 5B, the TiN film 31 that is a first layer as a glue film is formed on the inner surface of the fifth and the sixth contact holes 20e and 20f and the upper surface of the second interlayer insulating film 20. It is preferable to use SIP sputtering or SIP-EnCoRe sputtering to fill the TiN film 31 in the contact holes 20e and 20f to ensure excellent coverage. The conditions of such sputtering is similar to the above described embodiment.

As for the TiN film 31, thicker film thickness is better, though too thick causes high resistivity, deteriorates the filling shape of a W film formed in the following step and generates a crack in itself. Considering such as the above, about 50 nm film thickness is preferable.

Subsequently, an aluminum (Al) film 32a is formed on the TiN film 31 as a layer on the bottom surface inside the contact holes 20e and 20f as shown in FIG. 5C. If the intrusion pathway of hydrogen to the capacitor upper electrode 18 at tungsten growing is considered, the Al film 32a as a hydrogen barrier film needs not be formed on the inner side surface of the contact holes 20e and 20f but needs to be formed at least on the bottom surface.

As a result, of forming the Al film 32a in the above manner, film formation methods even such as collimator sputtering, long throw sputtering and ionized metal plasma (IMP) sputtering that have high straightness of metal element and poor side coverage can be used as well. As for the Al film 32a, thicker film thickness is better, though too thick deteriorates the filling shape of tungsten in the following step. Considering the above, about 50 nm film thickness is preferable.

Collimator sputtering allocates a collimating electrode between a target and a substrate, and selects an atom having many vertical components on the substrate surface and makes it reach the substrate. In this case, the cathode is allocated on the other side of the target from the substrate, and, in addition, a magnet that generates the magnetic field spreading from the center to the side is allocated on the other side of the target.

Long throw sputtering allocates a substrate and a target by long throw allocation and makes sputter particles reach the substrate surface in an almost perpendicular direction.

IMP sputtering has a configuration where a sputtered target material is ionized when passing plasma, and makes the target material reach a practically perpendicular direction to the biased substrate surface.

Next, as shown in FIG. 5D, the TiN film 33 of the second layer is formed as a glue layer on the TiN film 31 and the Al film 32a of the first layer. Because the Al film 32a as the H₂ barrier film has already been formed here, there are broad options in film formation methods of the TiN film 31 and either a sputtering method or a CVD method can be used.

In addition, because the Al film 32a is formed only on the bottom surface of the contact holes 20e and 20f, only the Al film 32a on the bottom surface should be covered with the TiN film 33 of the second layer. Therefore, even a film formation method with poor coverage of the TiN film 33 of the second layer, can be used, if it can form a film on the bottom.

Concretely, to form the TiN film 33 of the second layer, various film formation methods such as collimator sputtering, long slow sputtering and ionized metal plasma (IMP) sputtering that have high straightness of metal element or film formation methods such as SIP sputtering, SIP-EnCoRe sputtering and CVD method that have good coverage can be used. Though thicker film thickness is better, too thick causes high resistivity, deteriorates the filling shape of a W film formed in the following step and generates a crack on the TiN film 33. Considering the above, about 50 nm film thickness is preferable.

In addition, as explained in the first embodiment, it is preferable to form these films without exposure to the room's atmosphere by using the multi chamber device shown in FIG. 3, though it is also possible to form them with a different device per step. The selection can be changed depending on the situation of device handling.

Next, as shown in FIG. 5E, the W film 34 is formed by a CVD method by using the WF₆ gas and the contact holes 20e and 20f are completely filled thereby.

After that, the W film 34, the TiN film 33, the Al film 32a, and the TiN film 31 are removed from the upper surface of the second interlayer insulating film 20 by a CMP method and planarized. As a result, the W film 34, the TiN film 33, the Al film 32, and the TiN film 31 left in the contact holes 20e and 20f as shown in FIG. 5G become the fifth and the sixth conductive plug 29e and 29f.

As shown in FIG. 4A, the W film 34, the TiN film 33, the Al film 32 and the TiN film 31 deposited in the first to the fourth contact holes 20a to 20d on the upper side of the impurity diffusion areas 7a, 7b, 8a and 8b are also formed. They are used as the first to the fourth conductive plugs 29a to 29d.

After that, a metal film is formed on the second interlayer insulating film 20 and the first to the sixth conductive plugs 29a to 29f. As metal films, a TiN film, an Al film, a Ti film and a TiN film are formed in this order.

Subsequently, by patterning these metal films by a photolithographic method, as shown in FIG. 4B, a conductive pad 23 connected to the first conductive plug 29a of the second layer on the conductive plug 12a of the first layer in the center of the first well 3a, and wirings 24 to 27 connected to the second to the sixth conductive plugs 29b to 29f are formed.

After the conductive pad 23 and wirings 24 to 27 are formed, a third interlayer insulating film is formed, a conductive plug is formed, and additionally features such as a bit line is formed on the third interlayer insulating film, though the details are omitted.

As explained above, when the first contact hole 20e formed on the capacitor upper electrode 18 among the second interlayer insulating film 20 covering the ferroelectric capacitor Q1 is filled with a conductive material such as tungsten, the TiN film 31 that is the first layer has already been formed on the inner surface of the first contact hole 20e as an underlayer of a CVD film, the Al film 32a if formed on the bottom of it and the TiN film 33 of the second layer covering the Al film 32a is formed.

In this case, the Al film 32a, prevents hydrogen generated when the tungsten film 33 is grown in the fifth contact hole 20e by a CVD method from intruding into the capacitor upper electrode 18, thereby degradation by reduction of capacitor dielectric film 17a is prevented.

In addition, because the Al film 32a is formed not only on the bottom surface of the fifth contact hole 20e, but on the bottom surface of the first to the fourth and the sixth contact holes 20a to 20d and 20f, and on the second interlayer insulating film 20, hydrogen generated when growing the tungsten film on them is prevented from intruding into the second interlayer insulating film 20. As a result, hydrogen is prevented from intruding from within the second interlayer insulating film 20 to the ferroelectric capacitor Q1 by heat treatment after plugs 21a to 21d for vias, and contact plugs 21e and 21f are formed.

In addition, this structure in which the Al film 32a is formed at bottom surface of the contact holes 20a to 20f is an effective structure especially for the contact hole 20e on the capacitor upper electrode 18. However, although there is intrusion of hydrogen from the lower electrode 16, the amount is not significant compared with intrusion of hydrogen from the capacitor upper electrode 18. Further, the Al film 32 can be used on the lower electrode layer 16 as well because applying the same structure to the conductive plug 29e on the capacitor upper electrode 18 and the conductive plug 29f on the lower electrode layer 16 can simplify steps.

In addition, the contact holes 20a to 20d and the conductive plugs 29a to 29d of the second layer formed on the conductive plugs 12a to 12d of the first layer can be formed by different steps from those of the contact hole 20e and the conductive plug 29e on the capacitor upper electrode 18 due to differences in aspect ratios. In this case, an Al film needs not be formed in the contact holes 20a to 20d formed on the conductive plugs 12a to 12d of the first layer but a tungsten film can be grown after one layer of the TiN film is formed or a tungsten film can be grown after the Ti film and the TiN film are formed.

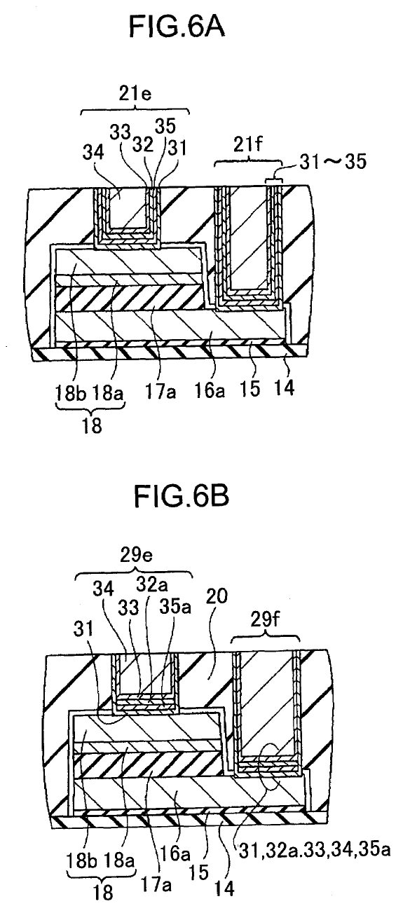

FIG. 6A and FIG. 6B are sectional views of the ferroelectric capacitor in the semiconductor device of a third embodiment of the present invention. FIG. 6A shows the structure of forming a Ti film 35 between the TiN film 31 and the Al film 32 of the first layer formed in the contact holes 20e and 20f on the capacitor upper electrode 18 and the lower electrode layer 16a described in the first embodiments.

In addition, FIG. 6B shows the structure formed by a Ti film 35a between the TiN film 31 and the Al film 32a of the first layer formed in the contact holes 20e and 20f on the capacitor upper electrode 18 and the lower electrode layer 16a shown in the second embodiment.

The Ti films 35 and 35a formed on the TiN film 31 function as a wet layer, which raises the mobility of Al on it so that the Al films 32 and 32a can be formed in the contact holes 20e and 20f with good shapes. In this case, because the Ti films 35 and 35a also have hydrogen barrier resistance, higher hydrogen barrier resistance can be achieved in the contact holes 20e and 20f.

The Ti films 35 and 35a need to be formed at least within the same range as the Al films 32 and 32a, and it is preferable to adopt the same film formation method as the Al films 32 and 32a. That is, in the case of the structure shown in FIG. 6A, it is preferable to adopt sputtering methods of SIP and SIP-EnCoRe for the Al film 32. In addition, in the case of the structure shown in FIG. 6B, it is preferable to adopt film formation methods having high straightness such as collimator sputtering, long slow sputtering, and IMP sputtering for the Al film 32a.

In addition, it is preferable that the Al films 32 and 32a is sandwiched by the TiN films so as not to touch the second interlayer insulating film 20 to prevent diffusion.

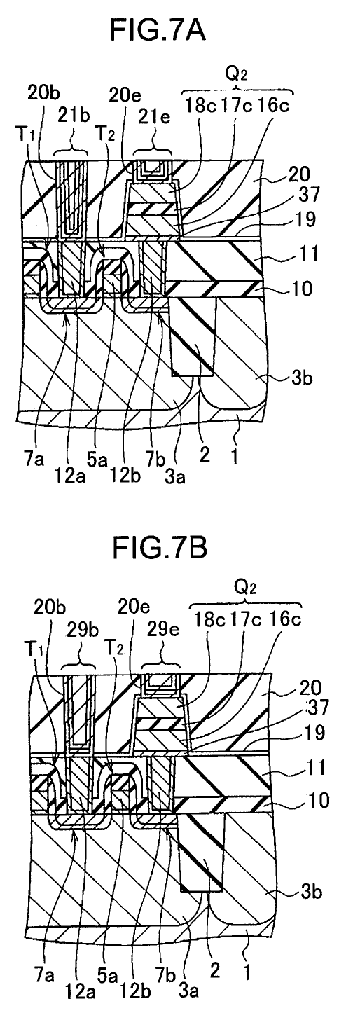

FIG. 7A and FIG. 7B are sectional views illustrating the semiconductor device of a fourth embodiment of the present invention. In FIG. 7A and FIG. 7B, the same marks as those in FIG. 1I and FIG. 1J and FIG. 4A and FIG. 4B show the same elements.

FIG. 7A and FIG. 7B, illustrate the state where the conductive plugs 12a and 12b of the first layer are connected onto the source/drain impurity diffusion layers 7a and 7b of the MOS transistors T₁ and T₂ covered with the first interlayer insulating film 11; the ferroelectric capacitor Q₂ in which the capacitor lower electrode 16b is connected to the conductive plugs 12a and 12b of the first layer is formed on the first interlayer insulating film 11; and further conductive plugs 21e and 29e in the structure having an Al film similar to FIG. 2 F and FIG. 5G in the contact hole 20e formed on the capacitor upper electrode 18c on the second interlayer insulating film 20 covering the ferroelectric capacitor Q₂.

In addition, in the above-mentioned embodiment, IrO₂ is used as the upper electrode of the ferroelectric capacitor, though the material for it is not limited to this but it can be, for example, platinum, Ir and another conductive material.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device comprising:
a first insulating film formed over a semiconductor substrate,
a capacitor formed over the first insulating film and including a lower electrode, a ferroelectric film and an upper electrode,
a second insulating film formed over the capacitor and the first insulating film,
a first contact hole formed in the second insulating film, and
a first conductive plug formed in the first contact hole and having a multilayer structure including a first aluminum film.

2. The semiconductor device according to claim 1,
wherein the first conductive plug includes a first glue film and a second glue film sandwiching the first aluminum film, and a conductive film formed over the first and the second glue films.

3. The semiconductor device according to claim 2,
wherein the first aluminum film is formed over a bottom surface of the first contact hole via the first glue film.

4. The semiconductor device according to claim 3,
wherein the first aluminum film is formed along a inner surface of the first glue film formed inside of the bottom surface and a sidewall surface of the first contact hole, and the first aluminum film is covered with the second glue film in the first contact hole.

5. The semiconductor device according to claim 2,
wherein the first glue film includes a titanium nitride film.

6. The semiconductor device according to claim 5,
further comprising: a titanium film formed between the first aluminum film and the titanium nitride film.

7. The semiconductor device according to claim 2,
wherein the second glue film includes a titanium nitride film.

8. The semiconductor device according to claim 2,
wherein the conductive film includes a tungsten.

9. The semiconductor device according to claim 1,
wherein a lower end of the first conductive plug is connected with the upper electrode of the capacitor.

10. The semiconductor device according to claim 1, further comprising:
a second contact hole formed in the second insulating film over the lower electrode, and
a second conductive plug formed in the second contact hole, having a multilayer structure including a second aluminum film.

11. The semiconductor device according to claim 1,
wherein the ferroelectric film includes PZT or bismuth.

12. A method for manufacturing a semiconductor device, comprising:
forming a first insulating film over a semiconductor substrate,
forming a capacitor including a lower electrode, a ferroelectric film and an upper electrode over the first insulating film,
forming a second insulating film over the first insulating film,
forming a first contact hole in the second insulating film over the upper electrode of the capacitor,
forming a first glue film along a bottom surface and a internal surface of the first contact hole,
forming a first aluminum film over the first glue film over the bottom surface of the first contact hole,
forming a second glue film over the first aluminum film, and
forming a first conductive film over the first and second glue films to fill the first contact hole.

13. The method for manufacturing the semiconductor device according to claim 12,
wherein the first aluminum film and the second glue film are formed along the internal surface and the bottom surface of the first contact hole.

14. The method for manufacturing the semiconductor device according to claim 13,
wherein the first aluminum film is formed by a SIP sputtering method or a SIP-EnCoRe sputtering method.

15. The method for manufacturing the semiconductor device according to claim 12,
wherein the first aluminum film formed over the bottom surface of the first contact hole is formed by any one of a collimator sputtering method, a long slow sputtering method, or ionized metal plasma sputtered method.

16. The method for manufacturing the semiconductor device according to claim 12,
wherein the first and the second glue films include titanium nitride films.

17. The method for manufacturing the semiconductor device according to claim 16,
further comprising: a titanium film formed between the titanium nitride film and the first aluminum film.

18. The method for manufacturing the semiconductor device according to claim 12,
wherein the conductive film includes tungsten.

19. The method for manufacturing the semiconductor device according to claim 12, further comprising:
forming a second contact hole in the second insulating film over the lower electrode,
forming a third glue film in the second contact hole,
forming a second aluminum film over the third glue film at the bottom surface of the second contact hole,
forming a fourth glue film over the second aluminum film, and
forming a second conductive film over the third and the fourth glue films.

20. The method for manufacturing the semiconductor device according to claim 19,
wherein the second aluminum film and the first aluminum film are formed at the same time, the third glue film and the first glue film are formed at the same time, the fourth glue film and the second glue film are formed at the same time and the second conductive film and the first conductive film are formed at the same time.
